(19) United States
(12) Patent Application Publication
(10) Pub. No.: US 2025/0123345 A1
(43) Pub. Date: Apr. 17, 2025

(54) SPECTRUM DATA FITTING

(71) Applicant: Imperial College Innovations Limited, London (GB)

(72) Inventors: Joram Matthias Posma, London (GB); Isabel Garcia Perez, London (GB); Elaine Holmes, London (GB); Gary Frost, London (GB)

(21) Appl. No.: 18/684,492

(22) PCT Filed: Aug. 12, 2022
(86) PCT No.: PCT/GB2022/052116

§ 371 Date: Feb. 16, 2024

(30) Foreign Application Priority Data
Aug. 16, 2021 (GB) 2111739.5

(51) Int. Cl. G01R 33/46; G01R 33/465

(52) U.S. Cl. CPC G01R 33/4625; G01R 33/465

(57) ABSTRACT

A method of fitting spectrum data to a model of biological substance data is disclosed. The method comprises receiving spectrum data, receiving fitting data for each of a plurality of biological substances, wherein fitting data comprises, for each of the plurality of biological substances: a number of reference multiplets for that biological substance, and for each reference multiplet, the position of the centre of that reference multiplet, the number of peaks for that reference multiplet, the relative amplitude of each peak, and the width of each peak. The method further comprises determining a fitting order of the reference multiplets, wherein the position of each reference multiplet in the fitting order is based on the number of possible overlaps with other reference multiplets comprised in the fitting data, starting with the fewest overlaps and ending with the most.

### FIELD

The present invention relates to fitting metabolite spectrum data to a model of metabolite data. The present invention also relates to generating a report and personalised advice based on comparison of fitted values with model references and client data.

### BACKGROUND

So-called western dietary patterns (that is, high in saturated fat, cholesterol, sodium, and added sugars; low in fruits, vegetables, and fibre) increase the risk of obesity and many non-communicable diseases, including diabetes, coronary heart disease, and cancers. Overall dietary patterns might be more informative about non-communicable disease risk than individual foods or nutrients. Many governments have introduced population-based policies aiming to improve dietary patterns and reduce disease burden. These policies have a common core goal (reflected in the WHO Global Strategy on Diet, Physical Activity and Health) of decreasing added sugar, sodium, and total fat consumption, and increasing intakes of wholegrain cereals, fruits, vegetables, and fibre. Results from the North Karelia project showed that such dietary change can contribute to decreased coronary heart disease mortality at the population level.

A major limitation of nutritional science is the objective assessment of dietary intake in free-living populations. Monitoring of dietary change in national surveys and large prospective studies relies on self-reported food intake using instruments such as food frequency questionnaires, dietary recall, and diet diaries; the prevalence of misreporting with these tools is estimated at 30-88%. Compounding this problem, bias in dietary misreporting (with under-reporting biased towards unhealthy foods and over-reporting towards fruits and vegetables) contributes to data inaccuracy and misinterpretation. Moreover, under-reporting of dietary energy intake is particularly common in obese individuals, which is a major concern considering the increasing prevalence of obesity worldwide.

### SUMMARY

According to a first aspect of the present invention, there is provided a method of fitting spectrum data to a model of biological substance data. The method comprises receiving spectrum data, receiving fitting data for each of a plurality of biological substances, wherein fitting data comprises, for each of the plurality of biological substances: a number of reference multiplets for that biological substance, and for each reference multiplet, the position of the centre of that reference multiplet, the number of peaks for that reference multiplet, the relative amplitude of each peak, and the width of each peak. The method further comprises determining a fitting order of the reference multiplets, wherein the position of each reference multiplet in the fitting order is based on the number of possible overlaps with other reference multiplets comprised in the fitting data, starting with the fewest overlaps and ending with the most. The method further comprises, for each reference multiplet, according to the fitting order: performing a first grid search to identify one or more first correlations between the reference multiplet and the spectrum data, wherein the grid search uses a first interval size, performing a second grid search on a range of wavelengths encompassing the one or more first correlations and using a second interval size smaller than the first interval size, wherein the second grid search identifies one or more second correlations, determining the second correlation corresponding to the best match between the reference multiplet and the spectrum data, in dependence upon the best match exceeds a detection threshold: assigning the biological substance corresponding to that reference multiplet as present, determining a concentration of that biological substance based on the portion of the spectrum data corresponding to the best matched reference multiplet, based on the determining concentration, generating a synthetic spectrum corresponding to the concentration of that biological substance; subtracting the synthetic spectrum from the spectrum data, removing all the reference multiplets for that biological substance from the fitting order, and updating the fitting order of the reference multiplets using the remaining reference multiplets.

The number of first/second correlations not necessarily equal.

A multiplet may have one or more peaks.

Known biological substances with distinct spectrum patterns, for example, urea in urine data, may be identified and subtracted from the spectrum before further analysis.

The biological substance fitting data may also include hyperparameter data. Hyperparameter data may include the number of intervals between peaks used in either the first or second grid search, the number of iterations applied when performing the first or second grid search.

Reference multiplets with the same number of overlaps may be further ordered by degree of overlap.

Overlap may be in wavelength or equivalents, for example, frequency, wavenumber chemical shift, amplitude, magnitude or other distinguishing metric.

Reference multiplets with the same degree of overlap may be further ordered by relative amplitude for a standard concentration.

Degree of concentration may be, for example, 1 millimol/l, or 1 nanomol/l.

The method may further comprise iteratively performing the first and/or second grid search.

The method further comprise normalising the spectrum data to the model of biological substance data.

Normalising the spectrum data to the model of biological substance data may comprise performing one or more amplitude multiplications to at least a portion the spectrum data. The at least a portion of the spectrum data may be portion corresponding to the best match correlation.

The detection threshold for the best match between the reference multiplet and the spectrum data may be six sigma.

The biological substance spectrum data (28) may be nuclear magnetic resonance spectrum data.

The first grid search between the biological substance fitting data and the spectrum data may be performed using a series of chemical shifts as centres of the muliplets.

The biological substance spectrum data is from a urine sample. The urine sample may be a 24 hour urine sample. The urine sample may be a spot urine sample.

The method may further comprise performing a baseline correction of all of at least part of the spectrum data.

The biological substance spectrum data may comprise data from biological substances from food.

Determining a fitting order of the reference multiplets may be based on the number of peaks in the reference multiplet.

For example, those multiplets with the greatest number of peaks may be fitted before those with a fewer number of peaks.

The biological substance may be a metabolite. A metabolite may be an intermediate or end product of a metabolic process.

The method may further comprise performing a baseline correction of all of at least part of the spectrum data. The baseline correction may be performed around the peaks representing each biological substance, or around each multiplet. The baseline correction may be performed using a convex hull.

The biological substance spectrum data may comprise data from biological substances from food.

The biological substance spectrum data may comprise data from biological substances from drugs, for example, from prescription drugs.

The method may be a computer implemented method.

The relative amplitude of each peak of the multiplet may be expressed as normalised amplitudes, where the highest peak of that multiplet is recoded as 1 and the heights of remaining peaks, if any, are expressed as a proportion.

According to a second aspect of the invention, there is provided a method of analysing biological sample data, the method comprising: receiving a biological sample, sample collection data including at least sample date and time which are associated with a unique sample identifier. The method further comprises storing sample collection data, sample date and time on a secure server, generating biological substance spectrum data from the biological sample, performing the method of the first aspect of the invention, identifying a model to apply to biological substance spectrum data based on sample collection date and/or time, standardising biological substance spectrum data axis to the number of data points used by the model, applying the model to biological substance spectrum data, comparing the fitted values of the spectrum data with the model references, obtaining adherence to a nutritional health score guidelines, generating figures for report based on the nutritional health score guidelines and the outcome of the application of the model, and generating a report and personalised advice based on comparison of fitted values with model references and client data.

The client data may be encrypted.

The method may further comprise generating a unique sample identifier; and sending a biological sample collection kit to a client associated with the unique sample identifier.

The biological substance spectrum data is nuclear magnetic resonance spectrum data.

The guidelines may be World Health Organisation healthy eating guidelines.

According to a third aspect of the invention, there is provided a method of obtaining the percentage adherence of biological substance spectrum data to a model. The method comprises receiving biological substance spectrum data (28), and sample collection time (24), receiving a model based on sample collection time, the model comprising a plurality of sub-models, for each sub-model: centring and scaling spectrum data based on model and sub-model parameters, multiplying the biological substance spectrum data by sub-model coefficients for each sub-model of the model, generating distribution of percentiles of predicted adherence, calculating the probability for each value of predicted adherence, calculating the median value of predicted adherence from the distribution of probabilities.

Sample collection time may include sample collection date.

The distribution of percentiles of predicted adherence may be between 0 and 100%.

The biological substance spectrum data may be from a urine sample.

The biological substance spectrum data may be from a urine sample.

According to a fourth aspect of the invention, there is provided a method of generating a model from biological substance spectrum data. The method comprises importing biological substance spectrum data and model parameters, applying repeated measures scaling to biological substance spectrum data, calculating a model by performing the following steps n number of times: allocating biological substance spectrum data to training, optimisation and test sets, obtaining scaling parameters and applying scaling parameters to training, optimisation and test data sets, calculating models having one or more different hyperparameters on the training data set, selecting optimal hyperparameters using the optimisation set, applying the/a set of model coefficients to the test data, obtaining estimate of predictive ability for current iteration, storing training set and test set for current iteration, calculating overall measure of predictive ability across all iterations, and outputting model parameters for all iterations.

The model parameters may be user-specified.

The user-specified parameters may comprise at least one from the list of: the type of scaling, number of iterations, the part of the data that will be split into a test portion, a different level of alpha.

According to a fifth aspect of the invention, there is provided a computer program which comprises instructions for performing a method according to any previous aspect.

According to a sixth aspect of the invention, there is provided a computer readable medium which stores a computer program according to the fifth aspect.

According to a seventh aspect of the invention, there is provided a computer system comprising: memory; at least one processing unit; wherein the processor is configured to perform the method of any previous aspect.

### BRIEF DESCRIPTION OF THE DRAWINGS

FIG. 1 is a schematic block diagram of a report generation system;

FIG. 2 is a schematic block diagram of a report retrieval system;

FIG. 3 is a schematic block diagram of a report;

FIG. 4 is a is a process flow diagram of generating a personalised diet report based on biological substance (e.g. metabolite) spectrum data;

FIG. 5 is a is a process flow diagram of fitting metabolite spectrum data to a model of biological substance (e.g. metabolite) data;

FIG. 6 is a process flow diagram of calculating a model of biological substance (e.g. metabolite) data;

FIG. 7 is a process flow diagram of obtaining the percentage adherence of biological substance (e.g. metabolite) spectrum data to a model;

FIG. 8 is a full metabolite spectrum;

FIG. 9 is an example of selected ranges of a metabolite spectrum;

FIG. 10 is an example of selected ranges of a metabolite spectrum with fitted metabolite peaks;

FIG. 11 is an example of selected ranges of a metabolite spectrum with fitted metabolite peaks;

FIG. 12 is metabolite spectrum data for individual metabolites; and

FIG. 13 is a table of example metabolite fitting data.

### DETAILED DESCRIPTION OF CERTAIN EMBODIMENTS

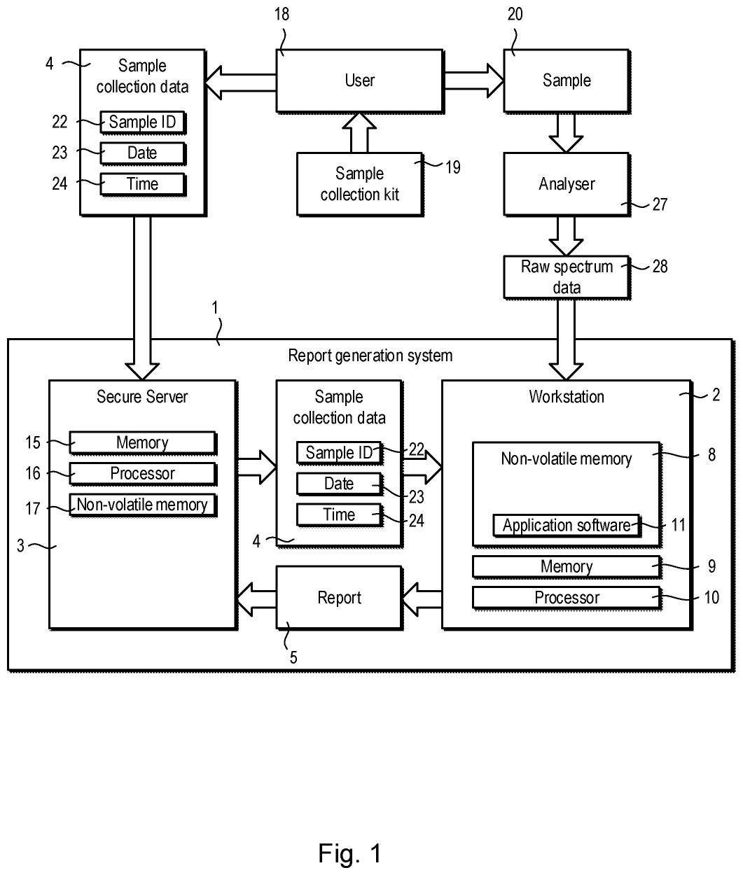

Referring to FIG. 1, a report generation system 1 is shown. The system includes a workstation 2 and a secure server 3. Sample collection data 4 (also referred to as metadata, urine sample metadata or simply “metadata”) is exchanged between the secure server 3 and the workstation 2. A report 5 (also referred to as a metabolite report, diet plan or spectrum analysis report) is exchanged between the workstation 2 and the secure sever 3.

The workstation 2 includes non-volatile memory 8, memory 9 and a processor 10. The non-volatile memory includes application software 11. The secure sever 3 includes memory 15, a processor 16, and non-volatile memory 17. The memory 9 may include fitting data (not shown) and hyperparameter data (not shown). The fitting data may include fitting data for each of a plurality of biological substances, wherein fitting data comprises, for each of the plurality of biological substances: a number of reference multiplets for that biological substance, and for each reference multiplet, the position of the centre of that reference multiplet, the number of peaks for that reference multiplet, the relative amplitude of each peak, and the width of each peak.

A user 18 (also referred to as a client), who wishes to have their diet analysed May request a sample collection kit 19. The sample collection kit may contain instructions for sample collection and a BD Vacutainer complete urine collection kits, including a complete system for urine collection, with a collection cup, one evacuated tube and a towel or towelette for patient cleansing prior to collection (see https://www.bd.com/en-us/offerings/capabilities/specimen-collection/urine-specimen-collection/bd-vacutainer-collection-and-transfer-products/bd-vacutainer-complete-urine-collection-kits for details of the kit contents). The sample collection kit 19 allows the user 18 to collect samples 20 from their body. The sample collection kit 19 may also allow for the safe storage and transport of the sample 20. The sample 20 may be any suitable sample 20 which can be used to assess the diet of the user, for example, a urine sample (for example, a spot urine sample or a 24-hour urine sample), a faecal sample, a blood or a saliva sample. Once a user 18 has collected a sample 20 using the sample collection kit 19, the user enters sample collection data 4 to the secure server 3 using an interface (not shown) such as a web page or a smartphone app. The sample collection data 4 includes a sample identification number 22 (also referred to as “sample ID”, or “sample identifier”), the date 23 and time 24 of the sample 20 collection. The sample ID 22 is included in the sample collection kit 19 to allow for the identification of the sample 20 and user 18. The sample ID 22 may contain information about the user 18, the type of analysis to be performed and the type of sample to be taken.

The user 18 sends the sample 20 to an analyser 27. The analyser 27 analyses the sample 20 and produces raw spectrum data 28 of the sample 20. The analyser 27 may be any suitable spectrometer, for example, a nuclear magnetic resonance spectrometer, for example, a 600 MHz Nuclear magnetic resonance spectrometer. The raw spectrum data 28 is then sent to the workstation 2 where it is stored in the non-volatile memory 8. The workstation 2 receives the sample collection data 4 from the secure server 3. The processor 10 processes the raw spectrum data 28 and the sample collection data 4 using the application software 11 to produce the report 5. The report 5 may then be sent to the secure server 3.

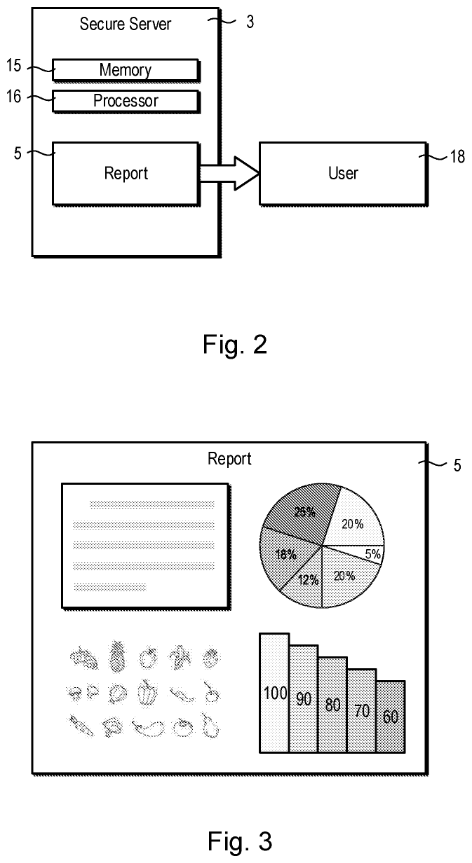

Referring also to FIG. 2, the user 18 can then request the report 5 using an interface, for example the same interface (not shown) as the user used to input the sample collection data 4.

Referring to FIG. 3, the report 5 includes information on diet nutrition requirements, including recommendations based on nutritional health score guidelines. The report may include written recommendations, Figures, graphs, and pictorial information.

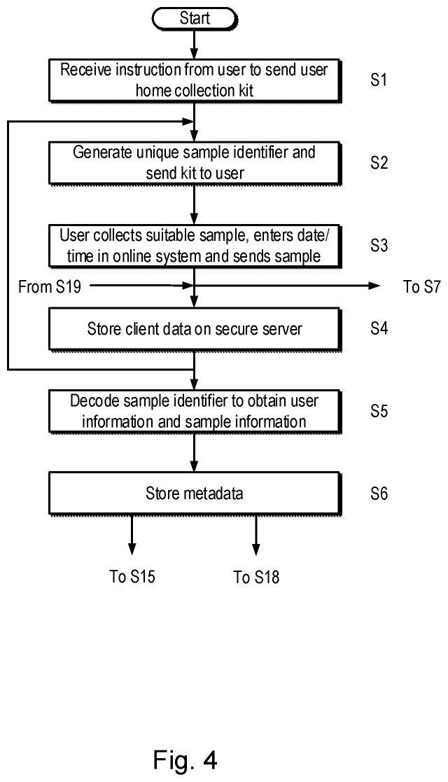

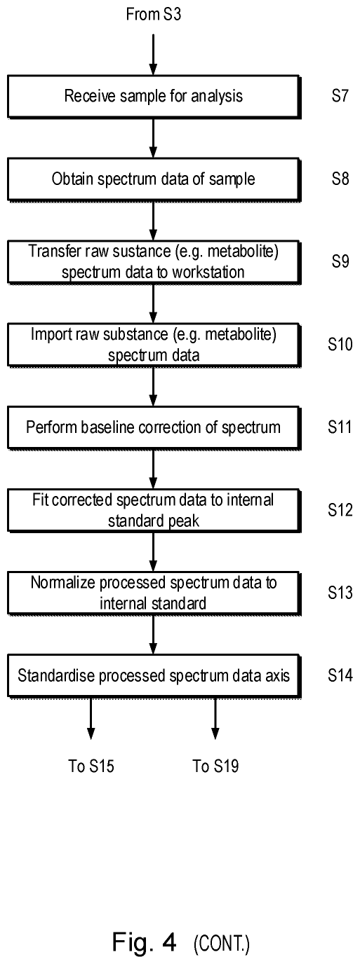

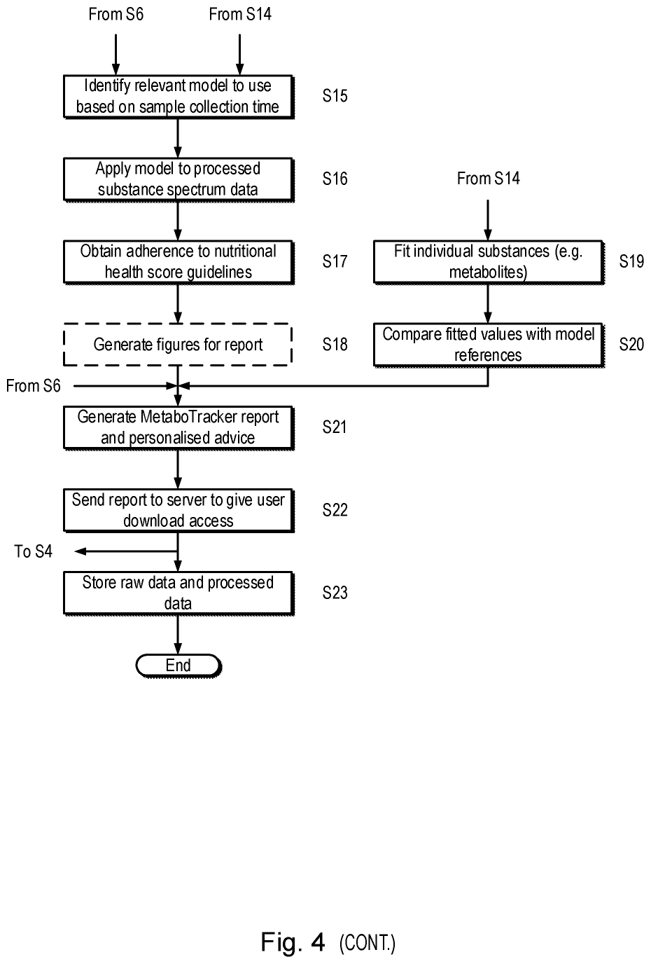

Referring to FIG. 4, a user 18 wishing to receive dietary and/or nutritional guidance and/or recommendations based on their current diet may request a sample collection kit 19. The when the request for a sample collection kit is received (step S1), a unique sample identifier 22 is generated (step S2). The generation of the unique sample identifier is performed by a computer that randomly generates a unique sequence of letters that are associated with a user 18 and the sample number and these are matched by a table look up. A sample collection kit 19 associated with the unique sample identifier 22 generated is then sent to the user 18 (step S2). The user 18 collects a suitable sample 20 (e.g. a urine sample), enters the date 23 and time 24 and sample ID 22 onto the secure server 3 via and interface, for example, a webpage, an app or by telephone and sends the sample 20 for spectrum analysis (step S3). The sample ID 22 may be encrypted on the secure sever 3. The client data is stored in the non-volatile memory 17 of the secure server 3 (step S4). Users 18 who wish to receive information about other biological substances which can be detected in user samples 20, for example drugs or drug metabolites, may also use this method.

The sample identifier 22 is decoded to obtain the user information and the sample information (step S5), also referred to as metadata 4. For example the decoded sample ID may contain user information such as name, sex, age, etc. and the sample information may include sample number, collection date and time. The metadata 4 for the sample 20 is stored in the non-volatile memory 17 of the secure sever 3 (step S6).

After step S3, the sample 20 is received form the user 18 for analysis (step S7). The sample 20 is then analysed to obtain spectrum data (step S8). For example, the sample 20 may be analysed for the presence and/or concentration of biological substances, e.g. metabolites, present in the sample 20. Metabolites may be intermediate or end products of metabolic reactions occur within biological cells. Metabolites may be low molecular weight organic compounds within a mass range of 50-1500 Daltons. The spectrum analysis may be nuclear magnetic resonance (NMR) spectroscopic analysis. The spectrum analysis may be mass spectrometry (e.g. with possible chromatographic separation by liquid chromatography, gas chromatography or capillary electrophoresis), or Raman spectroscopy. The spectrum data is then transferred to the workstation 2 (step S9). The raw spectrum data 28 may then be imported using the application software 11 (step S10). The raw spectrum data 28 is then corrected, for example using a baseline correction (step S11). As will be explained in more detail later, the raw spectrum 28 is then processed to fit the peaks of the peaks of known spectrum data (step S12). The fitted spectrum data is then calibrated to an internal standard, for example, normalized to an internal standard (step S13). The processed spectral data, for example processed metabolite spectral data, is then standardised (step S14), for example, if the spectrum data is NMR spectroscopy data, the chemical shift axis is standardised (using 1D cubic spline interpolation) to the number of data points used by one or more models applied later in the process. For example, there may be 16,000 points used by these models. For mass spectrometry, the peaks need to be aligned with the reference/model data so that the data are comparable, for Raman spectroscopy similar to NMR data processing, the spectrum is interpolated to the same number of points as the model data.

Using the metadata 4 and the standardised spectrum data, a model is identified using the time the sample was taken (step S15). If the sample was taken from 9 am-1 pm=model 1 (cumulative sample for after breakfast to before lunch), if from 1 pm-6 pm model 2 (cumulative model for after lunch to before dinner), if from 6 μm to 8 am=model 3 (cumulative model for after dinner, overnight and to before breakfast). The selected model is applied to the processed spectrum data (step S16). As will be explained in more detail later, the adherence of the processed spectrum data to the nutritional health guidelines is obtained (step S17). Optionally, pictorial representations of the adherence such as diagrams, figures, charts and plots are generated (step 18).

Once the processed spectrum data, for example processed metabolite spectrum data, is standardised in step S14, individual biological substances are fitted to a known spectrum of the biological substance data under investigation (step 19). For example, if the spectrum data is metabolite spectrum data, the individual metabolites are fitted to a known spectrum of the metabolite data. The fitted values of the processed spectrum data are then compared with the model reference values and a difference is obtained (step S20).

Using the stored metadata 4, the comparison between the fitted values of the processed spectrum data and the model reference values (step S20), and the (optional) pictorial representations of the adherence of the processed spectrum data to the model (step S18), a report 5 is generated. The report 5 may include personalised dietary advice for the user 18 (step S21). The report 5 is sent to the secure server 3 (step S22) and the user 18 given access to allow them to access the report 5 form the secure server 3 via an interface such as a webpage or smartphone app. The raw and processed data are stored on the secure server 3 in the non-volatile memory 17.

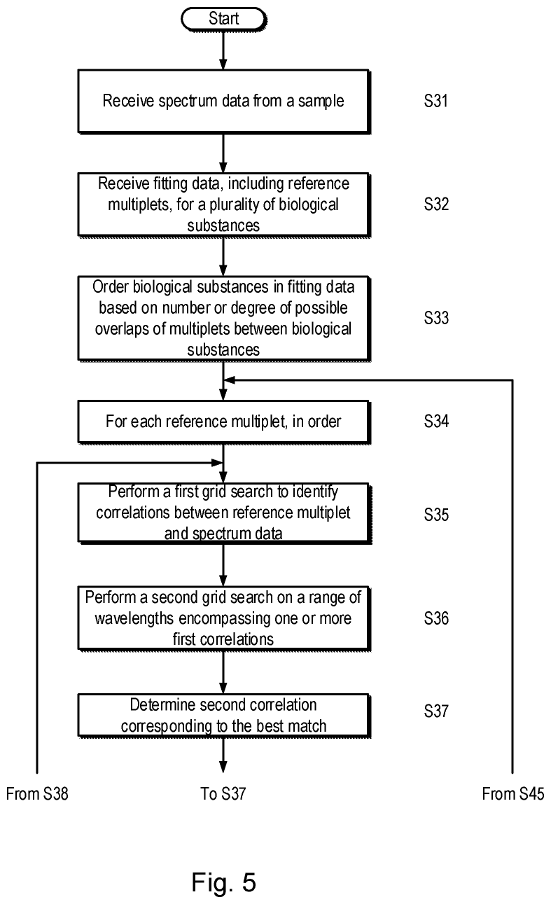

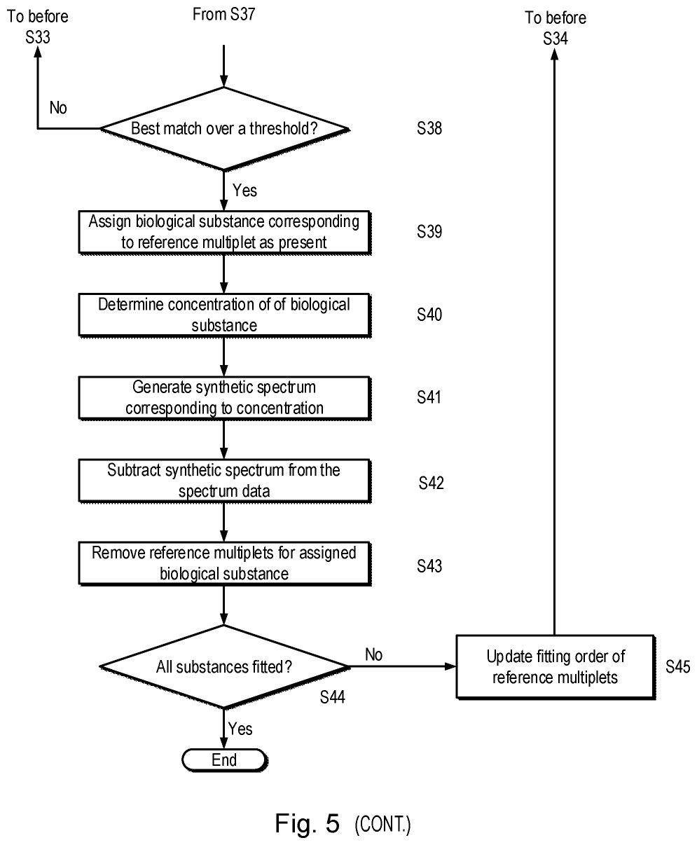

Referring to FIG. 5, the fitting of spectrum data to a model of biological substance data will now be explained. Spectrum data from the sample 20 is received (step S31). Biological substance fitting data, for example metabolite fitting data, which has been obtained from standardised analysis of the biological substances of interest in a sample of interest, for example, metabolites in a urine sample or metabolites in a faecal sample is also received (step S32). The samples are preferable in liquid form, or are capable of being made into a liquid sample, for example by suspension and/or by use of a solvent. The complexity of combined multiplets of the biological samples is known. A multiplet may have one or more peaks.

The biological substance fitting data comprises, for each of the plurality of biological substances: a number of reference multiplets for that biological substance, and for each reference multiplet, the position of the centre of that reference multiplet, the number of peaks for that reference multiplet, the relative amplitude of each peak, and the width of each peak.

A fitting order of the reference multiplets is determined (step S33). The position of each reference multiplet in the fitting order is based on the number of possible overlaps with other reference multiplets comprised in the fitting data, starting with the fewest overlaps and ending with the most.

Known biological substances with distinct spectrum patterns, for example, urea in urine data, may be identified and subtracted from the spectrum at any stage of the process and therefore not included for further analysis.

Reference multiplets having the same number of overlaps may be further ordered by degree of overlap, for example, of neighbouring multiplets. Overlap may be in wavelength or equivalents, for example, frequency, wavenumber chemical shift, amplitude, magnitude or other distinguishing metric. Reference multiplets with the same degree of overlap may be further ordered by relative amplitude for a standard concentration. Degree of concentration may be, for example, 1 millimol/l, 1 nanomol/l.

For each reference multiplet, according to the fitting order (step S34), a first grid search is performed (step S35) to identify one or more first correlations between the reference multiplet of the fitting data and the spectrum data from the sample. The grid search uses a first interval size to identify the correlations. Optionally, the first grid search may use more than one interval size, for example, in an iterative way.

A second grid search is then performed (step S36) on a range of wavelengths encompassing the one or more first correlations and using a second interval size smaller than the first interval size. The second grid search identifies one or more second correlations. The second correlation is determined corresponding to the best match between the reference multiplet and the spectrum data (step S37). The number of first and second correlations not necessarily equal.

The first and second grid searches may be performed iteratively.

The spectrum data may be normalised to the model of biological substance data. Normalising the spectrum data to the model of biological substance data may comprise performing one or more amplitude multiplications to at least a portion the spectrum data. The at least a portion of the spectrum data may be portion corresponding to the best match correlation.

The biological substance fitting data may also include hyperparameter data. Hyperparameter data may include the number of intervals between peaks used in either the first or second grid search, the number of iterations applied when performing the first or second grid search.

If the best match exceeds a detection threshold (step S38), the biological substance corresponding to that reference multiplet is assigned as present (step S39). If the best match does not exceed a detection threshold, then the process returns to before step S33. The detection threshold can be predetermined or calibrated, based on known values and an individual user's 18 biochemistry. The best match have a correlation significance threshold and be significant after multiple testing corrections using, for example, a Hommel's correction. Other multiple testing corrections may be applied.

The detection threshold for the best match between the reference multiplet and the spectrum data may be six sigma.

A concentration of that biological substance is determined based on the portion of the spectrum data corresponding to the best matched reference multiplet (step S40). The concentration may be determined by, for example, integration, but any suitable method may be used.

Based on the concentration determined, a synthetic spectrum corresponding to the concentration of that biological substance is generated (step S41). This synthetic spectrum is then subtracted from the spectrum data (step S42) so that the spectrum data no longer shows that biological substance as present. Next, all the reference multiplets for that biological substance from the fitting order are removed (step S43). If all substances are fitted, then the process ends (step S44). If there are biological substances remaining to be fitted, the fitting order of the reference multiplets using the remaining reference multiplets is updated (S45).

The biological substance spectrum data 28 may be nuclear magnetic resonance spectrum data. If the biological substance spectrum data 28 is nuclear magnetic resonance spectrum data, the first grid search between the biological substance fitting data and the spectrum data is performed using a series of chemical shifts as centres of the muliplets.

The biological substance spectrum data may be from a urine sample. The urine sample may be a 24-hour urine sample. The urine sample may be a spot urine sample. The biological substance spectrum data may comprise data from biological substances from food. The biological substance spectrum data may comprise data from biological substances from drugs, for example, from prescription drugs. The biological substance may be a metabolite. A metabolite may be an intermediate or end product of a metabolic process.

Alternatively, the biological substances present in the fitting data may be ordered according to decreasing complexity of combined multiplets, that is, the biological substances with the most complex multiplets (e.g. number of peaks in the multiplet) are ordered first. The biological substances present in the fitting data may be ordered according to the number of peaks in the reference multiplet. For example, those multiplets with the greatest number of peaks may be fitted before those with a fewer number of peaks.

Alternatively, the biological substances present in the fitting data may be ordered in the following way. First, biological substances in high concentrations in the sample 20 that do not overlap with other biological substances in the region where their multiplets appear. Second, biological substances in high concentrations that always appear in urine of which clear signals are always observable from a spectrum, for example, an NMR spectrum (within the region where we expect to see these clear peaks based on (potential) variability of the chemical shift). Third, the remaining biological substances that are important to the model used for fitting. To determine this set of biological substances, each biological substance is evaluated to determine which of these have clear multiplets in regions of the spectrum (e.g. NMR spectrum) with no overlap with other compounds. The stability of the positions (e.g. the stability of the chemical shift positions if using NMR spectrums) of the biological substances on the spectrum are also taken into account when determining this set. The order in which biological substances are fitted may be dynamic, for example, the order may be updated after a particular biological substance has been fitted and then eliminated from the data, leaving biological substances which are more easily fitted to the model.

If a biological substance has a multiplet that can be easily identified in the spectrum data (e.g. urea) all of its signals can be fitted. This could be at the beginning of the fitting process (where there is no overlap) or after peaks from other biological substances are fitted and removed from the data.

For example, there are biological substances whose peaks are always exactly at the same chemical shift in NMR spectrum data, which can be readily fitted. Other biological substances, e.g. citrate or 3-methylhistidine, tend to have variability in their peaks where they appear, e.g. where for creatinine this is ppm+0.01 this could be ppm+0.15 for 3-methylhistidine. In this case, there is higher potential for these biological substances (metabolites) to appear in a larger region, hence more potential overlap with other biological substances. These biological substances would be fitted later when they cannot be ‘confused’ with other compounds. These ordering methods may be performed instead of, or in combination with each other, depending on the type of biological substance data to be fitted.

It is also possible to start with metabolite that is most well defined in the fitting data, for example the least amount of overlap between its peaks and other metabolite's peaks. Likewise, metabolites that are known to always be present in urine samples and visible in NMR spectral data may be fitted first. For example, urea and creatinine are often present and may be fitted first, whereas paracetamol metabolites are only present if the person took paracetamol, hence these signals are only fitted when other metabolites more commonly found are fitted first. Metabolites which are deemed more important for a particular model over other metabolites may be prioritised over others which may exist in the sample but have not been identified in the particular model, for example arginine. Arginine is well defined, but may not be considered important in our model, hence arginine may be fitted at a later stage.

During the first grid search, local optima of the correlations are identified and evaluated, and then for each of these local optima, a second grid search is performed. The second grid search may be at smaller intervals and more intervals. The set of multiplets being evaluated (having one centre for each, one amplitude applied to all) that best fits the data is chosen based on it being at most six standard deviations of noise higher than the peak. This may be applied to all peaks in all multiplets. The sets of parameters are chosen that best fits the data where the amplitude is greater than zero, except when no positive correlations are found. If no positive correlations are found, the fit amplitude is zero and no fit found.

In other words, local optima of correlations between the biological substance fitting data and the spectrum data are identified by performing a first grid search using a number of intervals between two peaks of the biological substance fitting data as a hyperparameter. Next, a subset of correlations between the biological substance fitting data and the spectrum data are identified by performing a second grid search on these local optima using a greater number of intervals between two peaks of the biological substance fitting data than were used in the first grid search as a hyperparameter.

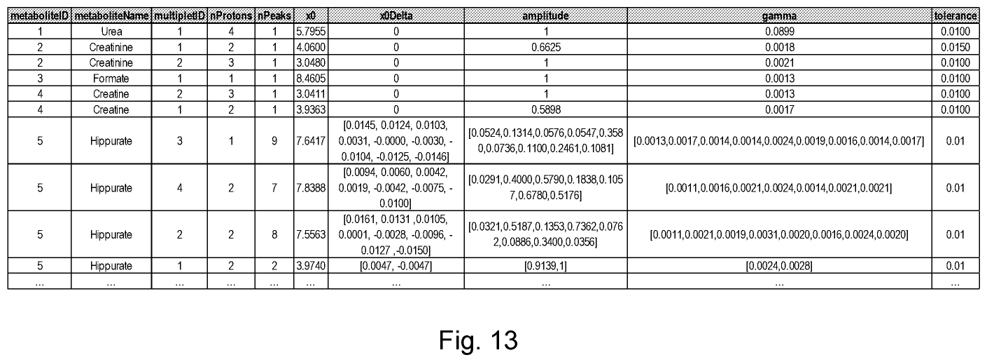

After performing these steps, a few potential fits per multiplet are found and stored (step S36). Each of these fits is evaluated see which combination best fits the data (step 37). This can be done by applying an amplitude multiplication to each set. This multiplication allows us to see if this combination of multiplets (that correlate locally) have the correct ratios expected from the peaks of the biological substance and if this gets close to the actual spectrum. For example, the amplitude found by the standard spectrum may be multiplied (e.g. see FIG. 13) and evaluate how close these get to the actual spectrum. For example, for the four hippurate peaks the same amplitude is used, because the hippurate standard spectrum has the ratios between peaks already there, so if concentration is twice as high then it is multiplied by two and all peaks grow by the same relative amount. So multiplying with 0.0456 (amplitude) achieves the same thing as multiplying by two. This generates the optimal fit found and then we evaluate how close it gets to the spectrum.

In other words a single correlation from the subset of correlations is selected by applying an amplitude multiplication to each of the spectrum data in the subset of correlations and comparing the ratios between at least first and second peaks in the multiplet of the biological substance spectrum data with the corresponding peaks in the biological substance fitting data.

The concentration of the biological substance in the spectrum data is then determined by integrating the multiplet of the biological substance spectrum data with the highest relative amplitude (step S38). The fit for the biological substance concerned is saved or stored (step S39). The identified multiplets of the spectrum data are eliminated from further processing by subtracting the identified multiplets from the spectrum data, allowing the remaining multiplets to be fitted more easily. The process is repeated until all peaks from all biological substances are fitted. The fitted values and spectrum location, and relative amplitude of the biological substance are then output.

The method of fitting the peaks may be expressed as:

$$f ( i ) = \begin{matrix}∀ \\ multipletID\end{matrix} {\sum }_{j = 1}^{nPeaks} \frac{( {a}_{j} \times {γ}_{j}^{2} )}{( {γ}_{j}^{2} + 4 \times {( x 0 + x 0 {δ}_{j} - {x}_{i} )}^{2} )}$$

Where a=amplitude, γ=gamma, xo=center of multiplet, xoδ=difference of peak to center, x=evaluate at this (ppm) value and f (i)=fit at index i in x. This may be performed for all multiplets, and for all peaks in each multiplet.

The method may be a computer implemented method.

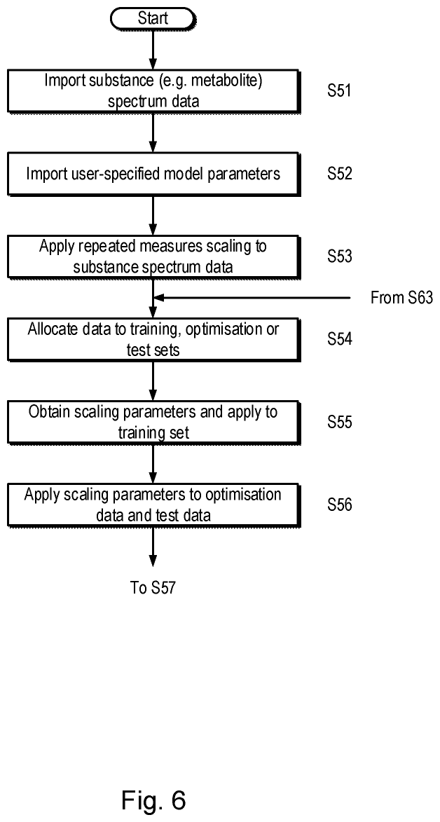

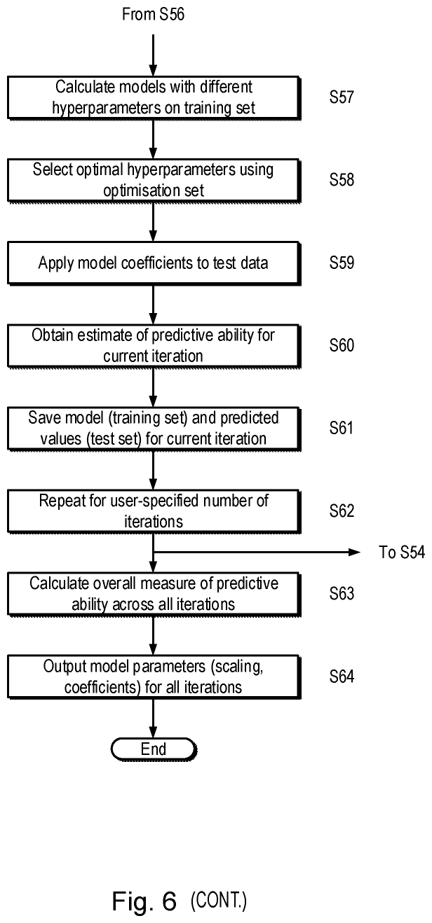

Referring to FIG. 6, the model calculation will now be described. The biological substance spectrum data is imported (step S51) along with user-specified model parameters (step S52). The user-specified model parameters include model hyperparameters, for example, how many iterations will be used when applying the model. There may be 1,000 iterations, 2,000 iterations or more than 2,000 iterations. The user-specified model parameters may also include the type of scaling to be applied, how the data should be split between training, test and optimisation subsets of data, for example, first the test set is split, if part=5 then ⅕th of the data is set aside in the test set where part=portion of the total set of data. For example, if there are 100 samples Part=5 means 20 samples are in the test set and the remaining 80 are used for training and validation. Then a further ⅕th is set aside in the optimisation set and remaining data is allocated to training set.

The user-specified model parameters may include the multiple testing correction type (types of false discovery rate (FDR) or family-wise error rate (FWER)) and significance level (also known as the alpha level), the maximum number of components the model will attempt to evaluate, whether or not the data will be corrected for orthogonal signals (for example, for repeated measures data). Further user-specified model parameters may include the number of bootstraps performed on the training model with optimal parameters chosen to find the spread of coefficients in the iteration. For example, 25 bootstraps may provide enough data and allow the data to be saved efficiently (for each model of 1,000 iterations, there are then 25 additional models so 25,000 in total, and across these 25,000 the variance is calculated of coefficients).

Repeated measures scaling is applied to the spectrum data (step S53). To apply the repeated measures scaling, data belonging to each individual is centred on the individual's mean spectrum. This is performed for each individual independently. Splitting of the data is performed per person (user 18) and not per sample, therefore, all samples from the same person (user 18) are always in the same set (that is, all in training set, or all in optimisation set, or all in the test set).

Next, the model is calculated by iteratively performing the following steps. The biological substance spectrum data is allocated to one of either training, test or optimisation. (step S54). The imported scaling parameters are applied to the training set (step S55). Next, the scaling parameters are applied to the optimisation set and the test set (step S56). A variety of models are then calculated using different hyperparameters on the training set of data (step S57). The hyperparameter used at this step may be the number of components in a partial least squares (PLS) model, however, other models may be used, for example, ridge regression in which case the hyperparameter that needs to be optimised is lambda (for regularisation). The optimisation set of data is then used to select the optimal hyperparameters to use (step S58). The coefficients calculated in step S57 are then applied to the test data (step 59). Performing this application of coefficients allows an estimate of the predictive ability for the current iteration to be obtained (step S60). The model (that is the training set) and the predictive values (the test set) are saved for the current iteration (step S61). The steps S54 to S61 are then repeated for a user-specified number of iterations (step S62).

When the number of iterations specified has been completed, the overall measure of predictive ability across all iterations is calculated (step S63) and the model parameters (for example, the scaling parameters and the coefficients) are outputted.

Known biological substances with distinct spectrum patterns, for example, urea in urine data, may be identified and subtracted from the spectrum before further analysis.

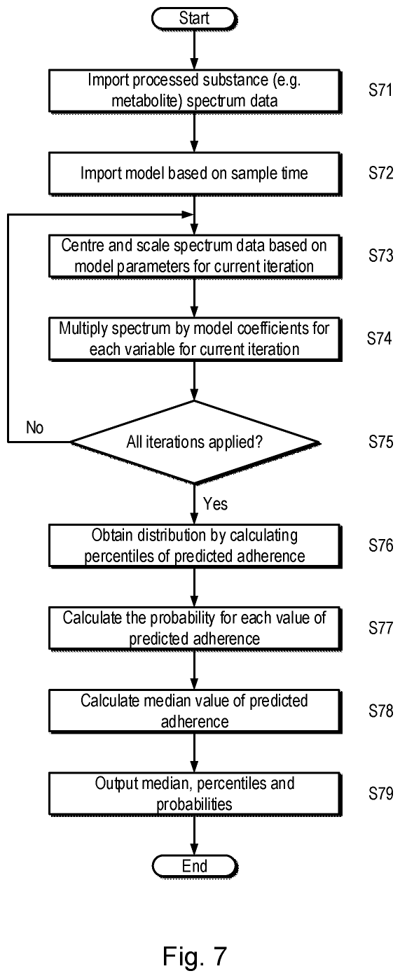

Referring to FIG. 7, how closely a user's 18 diet adheres to a set of healthy eating guidelines can be calculated. The processed spectrum data (e.g. biological substance or metabolite spectrum data) is imported (step S71). A model based on the sample time and, optionally, the spectrum data is imported (step S72). The model may be the model selected in steps S51 to S64. Iteratively, the spectrum data is centred and scaled based on model parameters for the current iteration (step S73) and the spectrum data is multiplied by the model coefficients for each variable for the current iteration (step S74). The process then checks to see whether all the iterations have been applied (step S75), if not, the process continues form step S73. If all iterations have been applied, a distribution is obtained by calculating the percentiles of predicted adherence (step S76). The probability for each value of predicted adherence is then calculated (step S77) and the median value of predicted adherence is calculated (step S78). Finally, the median, percentiles and probabilities are outputted and stored (step S79).

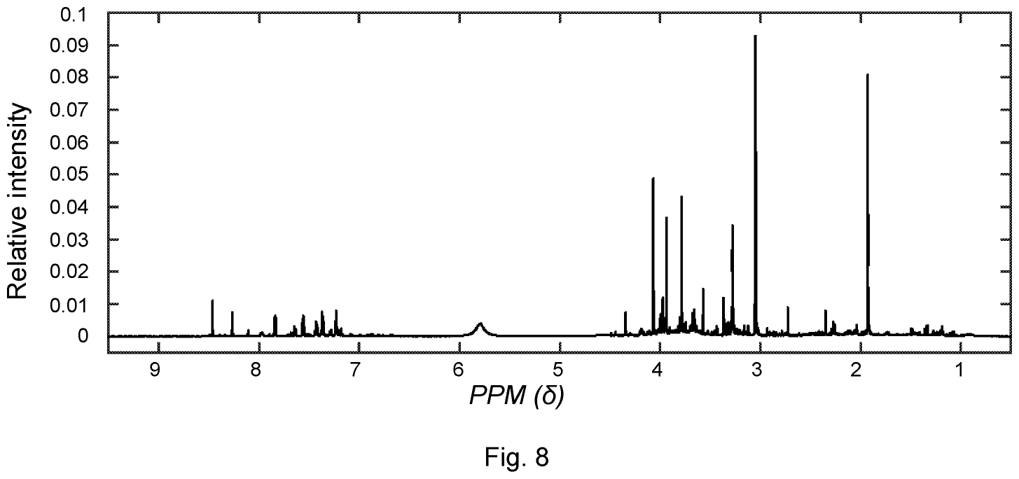

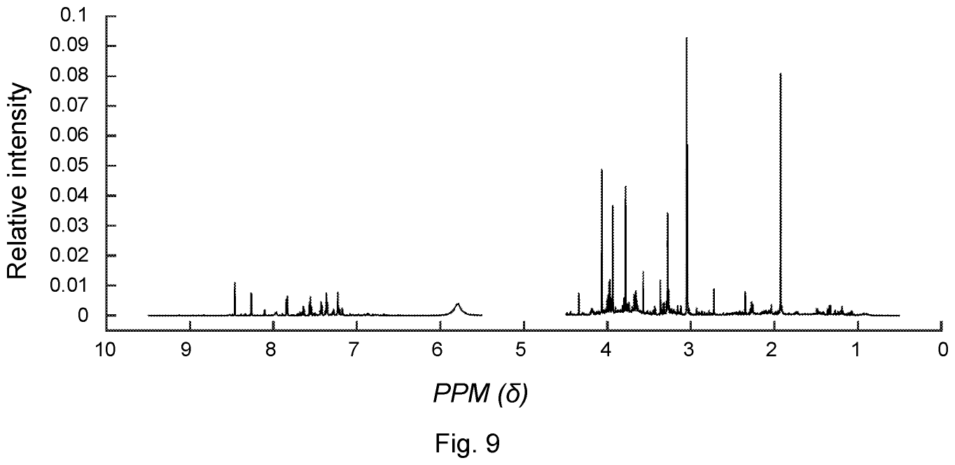

Referring to FIG. 8, a nuclear magnetic resonance (NMR) spectrum of metabolites from a urine sample is shown. The relative intensity of the chemical shift recorded from the NRM is shown. Referring also to FIG. 9, a subset of an NMR spectrum used in the model disclosed above is shown.

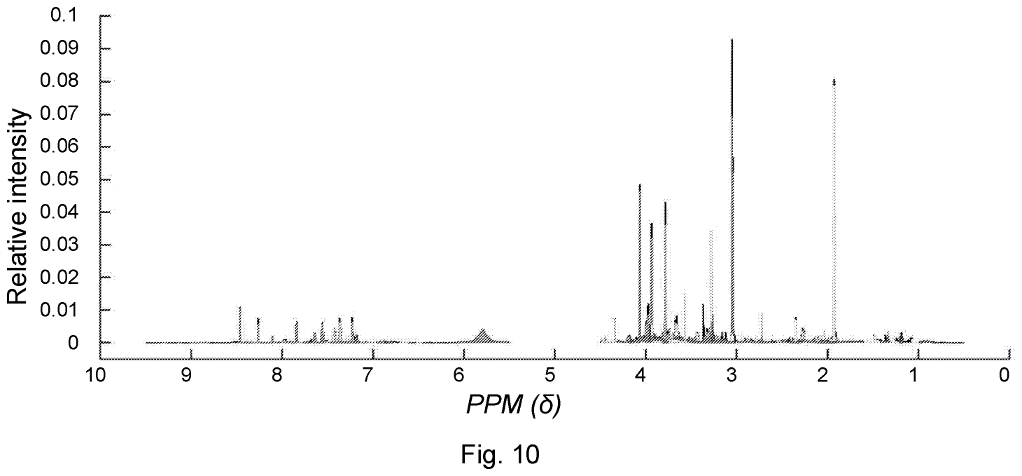

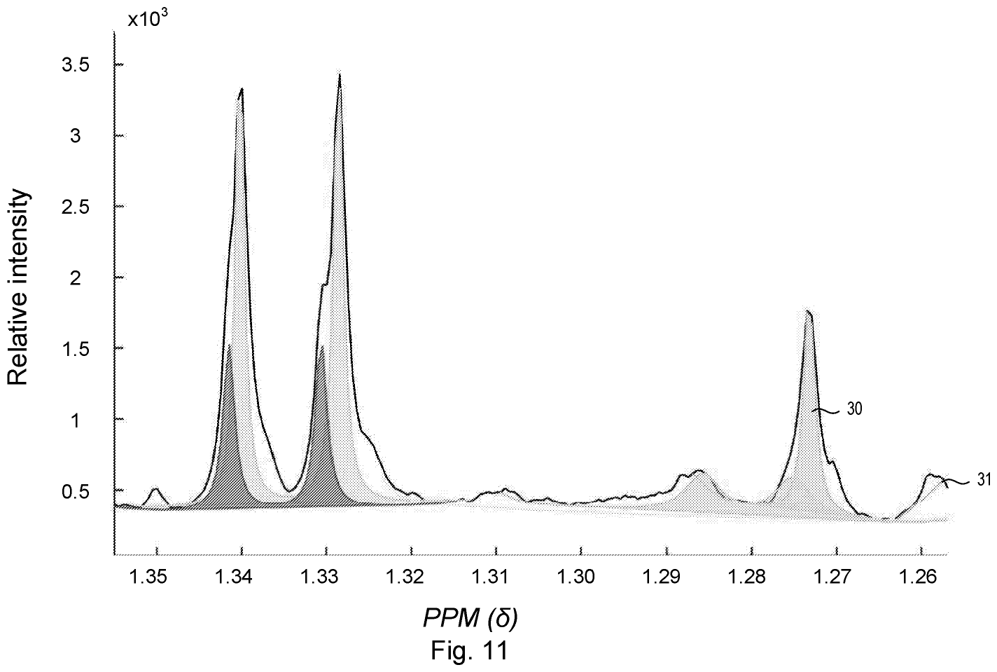

Referring to FIG. 10, a user's 18 NRM spectrum data from a urine sample is fitted to the NMR spectrum in FIG. 9. Referring to FIG. 11, the spectrum data 30 from a user's 18 urine sample 20 is fitted to the spectrum data 31 (which may be part of the biological substance fitting data) to assess the presence and/or concentration of particular biological substances in the sample 20 provided by the user.

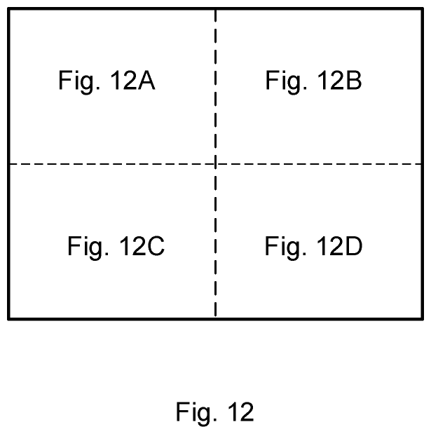

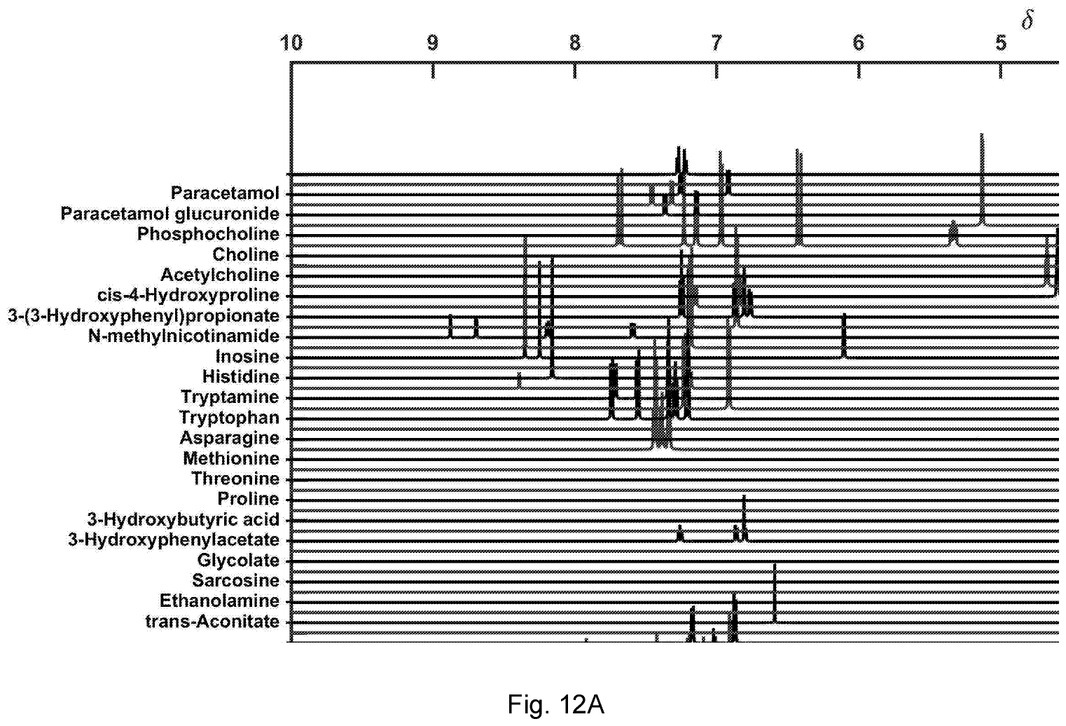

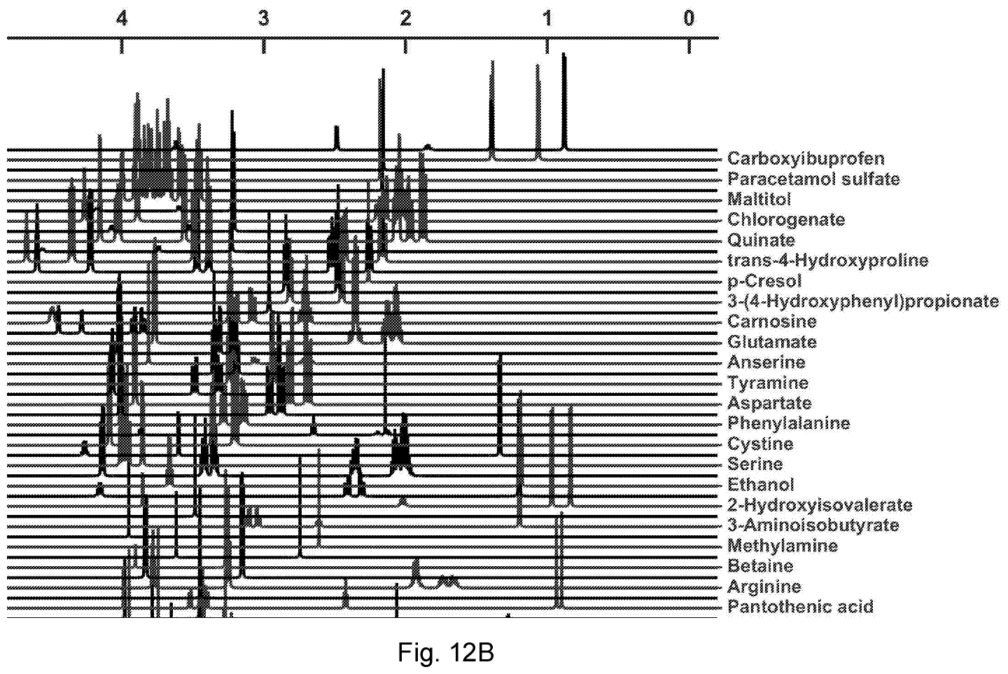

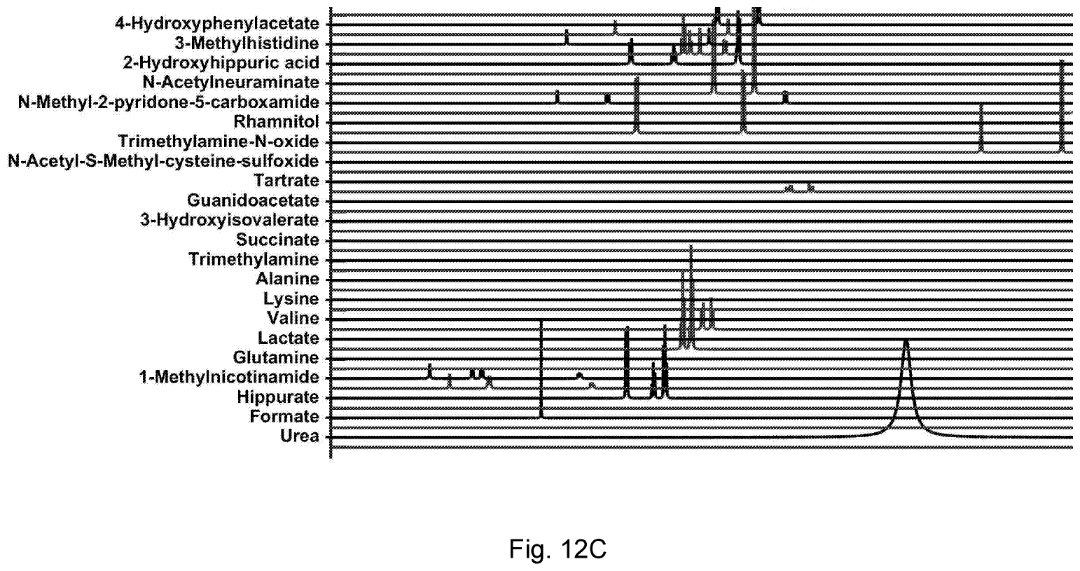

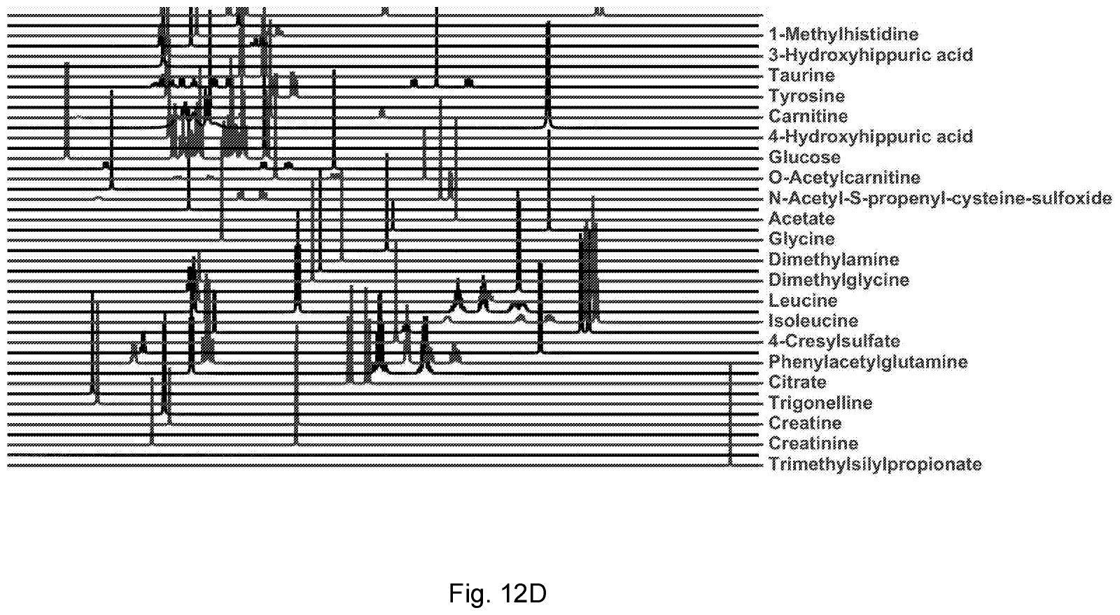

Referring to FIG. 12, the fitting data for the biological substances of interest for a user's 18 urine sample 20 are shown. FIGS. 12A-D show enlarged quarters of FIG. 12.

Referring to FIG. 13, an example table of ten metabolites of interest found in urine are shown along with the number of multiples for each metabolite, and the number of peaks for each multiplet. The relative amplitude of each peak is also shown, where all the peaks for a particular metabolite have been normalised, that is, the largest peak for each metabolite has an amplitude of one. Gamma, which may represent sensitivity, and tolerance are also given.

### Modifications

It will be appreciated that various modifications may be made to the embodiments hereinbefore described. Such modifications may involve equivalent and other features which are already known in the methods of biological substance and metabolite analysis and component parts thereof and which may be used instead of or in addition to features already described herein. Features of one embodiment may be replaced or supplemented by features of another embodiment.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A method of fitting spectrum data to a model of biological substance data, the method comprising:
receiving spectrum data,
receiving fitting data for each of a plurality of biological substances, wherein fitting data comprises, for each of the plurality of biological substances: a number of reference multiplets for that biological substance, and for each reference multiplet, the position of the centre of that reference multiplet, the number of peaks for that reference multiplet, the relative amplitude of each peak, and the width of each peak;
determining a fitting order of the reference multiplets, wherein the position of each reference multiplet in the fitting order is based on the number of possible overlaps with other reference multiplets comprised in the fitting data, starting with the fewest overlaps and ending with the most;
for each reference multiplet, according to the fitting order:
performing a first grid search to identify one or more first correlations between the reference multiplet and the spectrum data, wherein the grid search uses a first interval size;
performing a second grid search on a range of wavelengths encompassing the one or more first correlations and using a second interval size smaller than the first interval size, wherein the second grid search identifies one or more second correlations;
determining the second correlation corresponding to the best match between the reference multiplet and the spectrum data;
in dependence upon the best match exceeds a detection threshold:
assigning the biological substance corresponding to that reference multiplet as present;
determining a concentration of that biological substance based on the portion of the spectrum data corresponding to the best matched reference multiplet;
based on the determining concentration, generating a synthetic spectrum corresponding to the concentration of that biological substance;
subtracting the synthetic spectrum from the spectrum data;
removing all the reference multiplets for that biological substance from the fitting order; and
updating the fitting order of the reference multiplets using the remaining reference multiplets.

2. A method according to claim 1, wherein reference multiplets with the same number of overlaps are further ordered by degree of overlap.

3. A method according to claim 2, wherein reference multiplets with the same degree of overlap are further ordered by relative amplitude for a standard concentration.

4. A method according to claim 1, the method further comprising iteratively performing the first and/or second grid search.

5. A method according to claim 1, the method further comprising normalising the spectrum data to the model of biological substance data.

6. A method according to claim 1 wherein the biological substance spectrum data is nuclear magnetic resonance spectrum data.

7. A method according to claim 6 wherein the first grid search between the biological substance fitting data and the spectrum data is performed using a series of chemical shifts as centres of the muliplets.

8. A method according to claim 1 wherein the biological substance spectrum data is from a urine sample.

9. (canceled)

10. A method of claim 1 wherein the biological substance spectrum data comprises data from biological substances from food.

11. A method of claim 1 wherein determining a fitting order of the reference multiplets is based on the number of peaks in the reference multiplet.

12. A method of analysing biological sample data, the method comprising:
receiving a biological sample, sample collection data including at least sample date and time which are associated with a unique sample identifier;
storing sample collection data, sample date and time on a secure server;
generating biological substance spectrum data from the biological sample;
performing the method of claim 1;
identifying a model to apply to biological substance spectrum data based on sample collection date and/or time;
standardising biological substance spectrum data axis to the number of data points used by the model;
applying the model to biological substance spectrum data;
comparing the fitted values of the spectrum data with the model references;
obtaining adherence to a nutritional health score guidelines;
generating figures for report based on the nutritional health score guidelines and the outcome of the application of the model; and
generating a report and personalised advice based on comparison of fitted values with model references and client data.

13. A method of claim 12 further comprising generating a unique sample identifier; and
sending a biological sample collection kit to a client associated with the unique sample identifier.

14. A method of claim 12 wherein the biological substance spectrum data is nuclear magnetic resonance spectrum data.

15. (canceled)

16. A method of obtaining the percentage adherence of biological substance spectrum data to a model, the method comprising:
receiving biological substance spectrum data, and sample collection time;
receiving a model based on sample collection time, the model comprising a plurality of sub-models;
for each sub-model:
centring and scaling spectrum data based on model and sub-model parameters;
multiplying the biological substance spectrum data by sub-model coefficients for each sub-model of the model;
generating distribution of percentiles of predicted adherence;
calculating the probability for each value of predicted adherence;
calculating the median value of predicted adherence from the distribution of probabilities.

17. A method according to claim 16, wherein the biological substance spectrum data is from a urine sample.

18. A method of generating a model from biological substance spectrum data, the method comprising:
importing biological substance spectrum data and model parameters;
applying repeated measures scaling to biological substance spectrum data;
calculating a model by performing the following steps n number of times:
allocating biological substance spectrum data to training, optimisation and test sets obtaining scaling parameters and applying scaling parameters to training, optimisation and test data sets;
calculating models having one or more different hyperparameters on the training data set;
selecting optimal hyperparameters using the optimisation set;
applying the/a set of model coefficients to the test data;
obtaining estimate of predictive ability for current iteration;
storing training set and test set for current iteration;
calculating overall measure of predictive ability across all iterations; and
outputting model parameters for all iterations.

19. A method according to claim 18, wherein the model parameters are user-specified.

20. A method according to claim 19 wherein the user-specified parameters comprise at least one from the list of: the type of scaling, number of iterations, the part of the data that will be split into a test portion, a different level of alpha.

21. (canceled)

22. A computer readable medium having program instructions for performing the method of claim 1.

23. (canceled)

24. A computing device performing the method steps of claim 1.
